(19) United States
(12) Patent Application Publication
(10) Pub. No.: US 2026/0090385 A1
(43) Pub. Date: Mar. 26, 2026

(54) SEMICONDUCTOR MODULE COMPRISING A HOUSING

(71) Applicant: Infineon Technologies AG, Neubiberg (DE)

(72) Inventor: Georg Troska, Frondenberg (DE)

(73) Assignee: Infineon Technologies AG, Neubiberg (DE)

(21) Appl. No.: 19/292,485

(22) Filed: Aug. 6, 2025

(30) Foreign Application Priority Data
Sep. 25, 2024 (DE) 102024127731.9

(51) Int. Cl. H01L 23/40; H01L 23/04; H01L 23/24; H01L 23/49

(52) U.S. Cl. CPC H10W 40/611; H10W 72/50; H10W 76/161; H10W 76/47

(57) ABSTRACT

A semiconductor module comprises a substrate comprising a dielectric insulation layer and at least a first metallization layer arranged on the dielectric insulation layer, and a housing comprising sidewalls, the sidewalls defining an internal volume of the housing, wherein the housing is arranged such that the substrate is arranged within the internal volume defined by the sidewalls, with the metallization layer facing the internal volume of the housing, the housing comprises at least one mounting element for securely mounting the housing on a heat sink, and the sidewalls of the housing consist of an electrically conducting material.

### TECHNICAL FIELD

The instant disclosure relates to a semiconductor module comprising a housing.

### BACKGROUND

Semiconductor modules often include at least one substrate arranged in a housing. A semiconductor arrangement including a plurality of controllable semiconductor elements (e.g., two or more IGBTs) or non-controllable semiconductor elements (e.g., arrangements of diodes) is arranged on each of the at least one substrate. Each substrate usually comprises a substrate layer (e.g., a ceramic layer), a first metallization layer deposited on a first side of the substrate layer and a second metallization layer deposited on a second side of the substrate layer. The controllable semiconductor elements are mounted, for example, on the first metallization layer. The second metallization layer may be attached to a base plate, which forms part of the module, or may be pressed against a heat sink.

In modules without base plates, the housing is usually attached to the heat sink by a suitable fixing means. Fixing the housing to the heat sink also serves to press the substrate against the heat sink in order to ensure a homogenous contact between them to increase heat dissipation towards the heat sink. The housing, therefore, is required to be solid enough in order to be able to reliably exert a certain amount of pressure on the substrate.

There is a need for a semiconductor module comprising a housing that is solid enough to be able to reliably exert a certain amount of pressure on the substrate in order to provide a satisfying contact between the substrate and a heat sink.

### SUMMARY

A semiconductor module includes a substrate including a dielectric insulation layer and at least a first metallization layer arranged on the dielectric insulation layer, and a housing including sidewalls, the sidewalls defining an internal volume of the housing, wherein the housing is arranged such that the substrate is arranged within the internal volume defined by the sidewalls, with the metallization layer facing the internal volume of the housing, the housing includes at least one mounting element for securely mounting the housing on a heat sink, and the sidewalls of the housing consist of an electrically conducting material.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a semiconductor module.

FIG. 2 is a three-dimensional view of a housing for a semiconductor module according to embodiments of the disclosure.

FIG. 3 is a three-dimensional cross-sectional view of a semiconductor module according to embodiments of the disclosure.

FIG. 4 is a cross-sectional view of a section of a semiconductor module according to embodiments of the disclosure.

FIG. 5 is a cross-sectional view of a section of a semiconductor module according to further embodiments of the disclosure.

FIG. 6 is a cross-sectional view of a section of a semiconductor module according to further embodiments of the disclosure.

FIG. 7 is a cross-sectional view of a section of a semiconductor module according to further embodiments of the disclosure.

FIG. 8 is a cross-sectional view of a section of a semiconductor module according to further embodiments of the disclosure.

FIG. 9 is a cross-sectional view of a section of a semiconductor module according to further embodiments of the disclosure.

FIG. 10 is a cross-sectional view of a section of a semiconductor module according to further embodiments of the disclosure.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description, as well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable). A semiconductor body as described herein may be made from (doped) semiconductor material and may be a semiconductor chip or be included in a semiconductor chip. A semiconductor body has electrically connecting pads and includes at least one semiconductor element with electrodes.

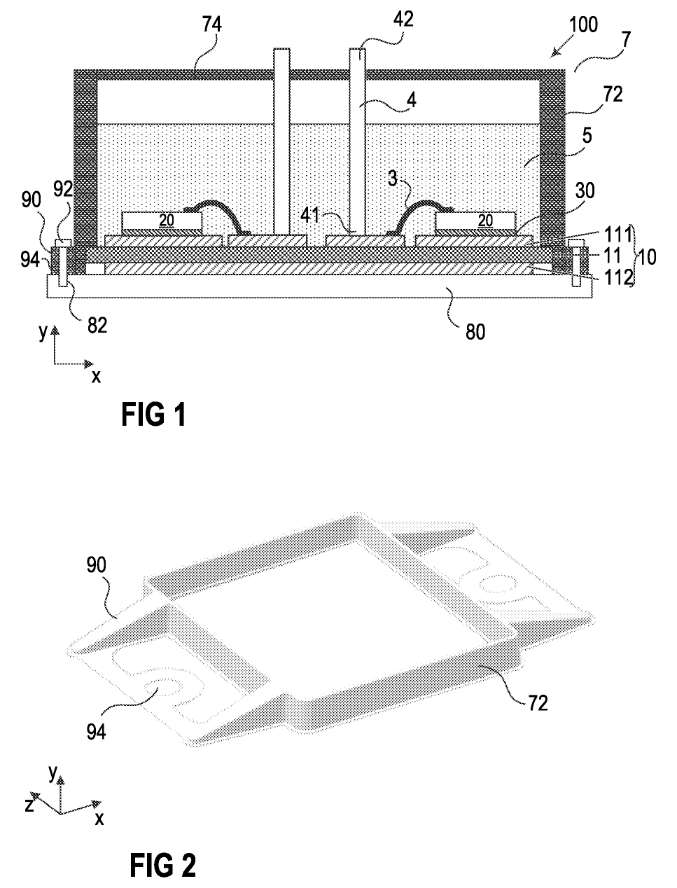

Referring to FIG. 1, a cross-sectional view of a semiconductor module 100 is illustrated. The semiconductor module 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 11 may consist of or include one of the following materials: Al₂O₃, AlN, SiC, BeO or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, or BN and may have a diameter of between about 1µm and about 50µm. The substrate 10 may also be a conventional printed circuit board (PCB) having a non-ceramic dielectric insulation layer 11. For instance, a non-ceramic dielectric insulation layer 11 may consist of or include a cured resin.

The substrate 10 is arranged in a housing 7. The housing 7 comprises sidewalls 72 and a top or cover 74 (only referred to as cover in the following). The substrate 10 is mounted on a heat sink 80. In some semiconductor modules 100, even more than one substrate 10 is arranged on a single heat sink 80. The heat sink 80 forms a support surface for the module 100. The cover 74 of the housing 7 can either be a separate cover (or lid) that can be removed from the sidewalls, or may be integrally formed with the sidewalls 72 of the housing 7. In the latter case, the cover 74 and the sidewalls 72 of the housing 7 may be formed as a single piece such that the cover 74 cannot be removed from the sidewalls 72 without damaging or destroying the housing 7. The cover 74, however, is generally only optional and may also be omitted.

One or more semiconductor bodies 20 may be arranged on the substrate 10. Each of the semiconductor bodies 20 arranged on the substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable controllable or non-controllable semiconductor element.

The one or more semiconductor bodies 20 may form a semiconductor arrangement on the substrate 10. In FIG. 1, only two semiconductor bodies 20 are exemplarily illustrated. The second metallization layer 112 of the substrate 10 in FIG. 1 is a continuous layer. The first metallization layer 111 is a structured layer in the example illustrated in FIG. 1. “Structured layer” means that the first metallization layer 111 is not a continuous layer, but includes recesses between different sections of the layer. Such recesses are schematically illustrated in FIG. 1. The first metallization layer 111 in this example includes four different sections. Different semiconductor bodies 20 may be mounted to the same or to different sections of the first metallization layer 111. Different sections of the first metallization layer may have no electrical connection or may be electrically connected to one or more other sections using, e.g., bonding wires 3. Electrical connections 3 may also include connection plates or conductor rails, for example, to name just a few examples. The one or more semiconductor bodies 20 may be electrically and mechanically connected to the substrate 10 by an electrically conductive connection layer 30. Such an electrically conductive connection layer may be a solder layer, a layer of an electrically conductive adhesive, or a layer of a sintered metal powder, e.g., a sintered silver powder, for example.

The semiconductor module 100 illustrated in FIG. 1 further includes terminal elements 4. The terminal elements 4 are electrically connected to the first metallization layer 111 and provide an electrical connection between the inside and the outside of the housing 7. The terminal elements 4 may be electrically connected to the first metallization layer 111 with a first end 41, while a second end 42 of the terminal elements 4 protrudes out of the housing 7. The terminal elements 4 may be electrically contacted from the outside at their second ends 42. The terminal elements 4 illustrated in FIG. 1, however, are only examples. Terminal elements 4 may be implemented in any other way and may be arranged at any other position. For example, one or more terminal elements 4 may be arranged close to or adjacent to the sidewalls of the housing 7. Any other suitable implementation is possible. The terminal elements 4 may consist of or include a metal such as copper, aluminum, gold, silver, or any alloys thereof, for example. The terminal elements 4 may be electrically and mechanically connected to the substrate 10 by an electrically conductive connection layer (not specifically illustrated for the terminal elements 4 in FIG. 1). Such an electrically conductive connection layer generally may be a solder layer, a layer of an electrically conductive adhesive, or a layer of a sintered metal powder, e.g., a sintered silver powder, for example.

Conventional semiconductor modules 100 generally further include a casting compound 5. The casting compound 5 may consist of or include a silicone gel or may be a rigid molding compound, for example. The casting compound 5 may at least partly fill the interior of the housing 7, thereby covering the components and electrical connections that are arranged on the substrate 10. In the illustrated embodiment, terminal elements 4 may be partly embedded in the casting compound 5. At least their second ends 42, however, are not covered by the casting compound 5 and protrude from the casting compound 5 through the housing 7, to the outside of the housing 7. The casting compound 5 is configured to protect the components and electrical connections inside the semiconductor module 100, in particular inside the housing 7, from certain environmental conditions and mechanical damage.

The housing 7 is usually attached to the heat sink 80 by means of suitable mechanical connection elements, e.g., by means of rivets, screws or bolts 92. The housing 7 may comprise one or more mounting elements 90 for securely mounting the housing 7 on the heat sink 80, for example. As is schematically illustrated in FIG. 1, each mounting element 90 of the at least one mounting element 90 may comprise at least one hole 94. Each hole is aligned with a corresponding hole 82 in the heat sink 80. According to one example, at least the holes 82 in the heat sink 80 may be threaded holes. Each screw or bolt 92 extends through a different hole 94 of the at least one hole 94 in the at least one mounting element 90 and into a corresponding hole 82 in the heat sink 80. By tightening the screws 92 or by firmly pressing down the bolts 92, the housing 7 is securely attached to the heat sink 80. The housing 7, at the same time, may be used to press the at least one substrate 10 against the heat sink 80. For example, the sidewalls 72 may comprise one or more protrusions and the at least one substrate 10 (i.e. an edge region of the at least one substrate 10) may be arranged between the one or more protrusions and the heat sink 80. That is, the sidewalls 72 contact the substrate 10 from above on a top surface of the dielectric insulation layer 11, wherein a top surface of the dielectric insulation layer 11 is a surface facing away from the heat sink 80. In this way, a homogenous contact between the substrate 10 and the heat sink 80, and thus a satisfying heat dissipation from the substrate 10 towards the heat sink 80 may be provided. The housing 7, therefore, is required to be solid enough in order to be able to reliably exert a certain amount of pressure on the substrate 10.

Housings 7 for semiconductor modules are often made from plastic materials. Most plastic materials, however, are elastic to a certain degree and, therefore, have inadequate material properties (i.e., they are too soft) and are not able to apply high forces on the substrate 10. Mixing somewhat harder materials such as, e.g., glass fibers, into the plastic material of a housing 7 helps to increase the overall hardness of the housing 7, but at the same time also increases the brittleness of the material.

A semiconductor module 100 according to embodiments of the disclosure comprises a substrate 10 comprising a dielectric insulation layer 11 and at least a first metallization layer 111 arranged on the dielectric insulation layer 11, and a housing 7 comprising sidewalls 72, the sidewalls 72 defining an internal volume of the housing 7, wherein the housing 7 is arranged such that the substrate 10 is arranged within the internal volume defined by the sidewalls 72, with the metallization layer 111 facing the internal volume of the housing 7, the housing 7 comprises at least one mounting element 90 for securely mounting the housing 7 on a heat sink 80, and the sidewalls 72 of the housing 7 consist of an electrically conducting material.

A semiconductor module 100 according to further embodiments of the disclosure comprises a substrate 10 comprising a dielectric insulation layer 11 and at least a first metallization layer 111 arranged on the dielectric insulation layer 11, a heat sink 80, and a housing 7 comprising sidewalls 72, the sidewalls 72 defining an internal volume of the housing 7. The substrate 10 is arranged on the heat sink 80 with the first metallization layer 111 facing away from the heat sink 80. Further, the housing 7 is arranged on the heat sink 80 such that the substrate 10 is arranged within the internal volume defined by the sidewalls 72. The housing 7 is in direct contact with the dielectric insulation layer 11 of the substrate 10 and with the heat sink 80. Further, the housing 7 comprises at least one mounting element 90 for securely mounting the housing 7 on the heat sink 80, and the sidewalls 72 of the housing 7 consist of an electrically conducting material.

For example, the sidewalls 72 may consist of a metal material. The metal material may consist of or comprise any of the following materials: aluminum, copper, brass, tin, steel, and combinations thereof. Such electrically conductive materials, e.g., metals, are generally much harder and may be less elastic than plastic materials that are commonly used to form housings 7 for semiconductor modules. Electrically conducting materials such as, e.g., metals, may be formed and shaped with comparably simple methods such as, e.g., bending, cutting, casting or deep drawing. A semiconductor module 100 according to embodiments of the disclosure, therefore, may be produced at comparably low costs.

As is schematically illustrated in FIG. 2, the sidewalls 72 and the one or more mounting elements 90 may be integrally formed as a single piece. It is, however, generally also possible that the one or more mounting elements 90 are separate elements that are attached to the sidewalls 72 of the housing 7. Mounting elements 90 may be attached to the sidewalls 72 in any suitable way, e.g., gluing or screwing, or by means of suitable plug connection. If, however, mounting elements 90 are integrally formed with the sidewalls 72 of the housing 7, the housing 7 may be manufactured in a very easy and cost effective way.

Each mounting element 90 of the at least one mounting element 90 may comprise at least one first hole 94. When the housing 7 is arranged on the heat sink 80, each first hole 94 may be aligned with a different hole 82 of one or more second holes 82 in the heat sink 80. The semiconductor module 100 may further comprise at least one screw or bolt 92, each of the at least one screw or bolt 92 extending through a different first hole 94 of the at least one first hole 94 in the at least one mounting element 90 and into a corresponding second hole 82 in the heat sink 80. In this way, the mounting elements 90 may be securely attached to the heat sink 80. As the one or more mounting elements 90 are integrally formed with or suitably attached to the sidewalls 72 of the housing 7, the housing 7 is also securely attached to the heat sink 80 by means of the screws or bolts 92. As the substrate 10 (i.e. an edge region of the substrate 10) is arranged between the sidewalls and the heat sink 80, the substrate 10 is pressed against the heat sink 80 by means of the sidewalls 72, when the screws or bolts 92 are inserted into the first and respective second holes 94, 82.

The housing 7 may be designed in such a way that the forces pressing the substrate 10 onto the heat sink 80 are (evenly) distributed along the edges of the substrate 10. That is, a protrusion or other contact element of the housing 7 that is in direct contact with the substrate 10 may extend continuously along a circumference of the substrate 10. In this way, the pressure exerted on the substrate 10 by means of the housing 7 is evenly distributed along the entire circumference of the substrate 10.

According to some embodiments of the disclosure, the housing 7 comprises two mounting elements 90 arranged on opposite sides of the housing 7, as is exemplarily illustrated in FIG. 2. In this way, forces pressing the substrate 10 onto the heat sink 80 may be evenly distributed along the edges of the substrate 10. According to other examples, a housing 7 may comprise four mounting elements 90, each mounting element 90 being attached to or integrally formed with a different sidewall 72 of the housing 7. Most housings 7 have a square or rectangular shape. That is, most housings 7 comprise four sidewalls 72. Generally, however, any number of sidewalls of three or more is generally possible. Even housings having a circular shape and therefore only a single circular sidewalls 72 are generally possible.

As the sidewalls 72 of the housing 7 consist of an electrically conducting material (e.g., a metal), there is a risk of electric flashovers or short circuits occurring between the first metallization layer 111 and the sidewalls 72. As has been described above, the semiconductor module 100 may further comprise a casting compound 5 which at least partly fills the internal volume defined by the sidewalls 72. The casting compound 5 may cover the substrate 10, and may at least partly cover components and electrical connections arranged on the substrate 10. For example, semiconductor bodies 20 and electrical connections 3 may be entirely covered by the casting compound 5. Other elements such as, e.g., terminal elements 4, however, may only be partly covered by the casting compound 5. A portion of the casting compound 5 may be arranged between the sidewalls 72 and the first metallization layer 111 of the substrate 10, thereby electrically insulating the sidewalls 72 from the first metallization layer 111 (see, e.g., FIG. 1). That is, the first metallization layer 111 does not directly contact the sidewalls 72. Instead, there is a gap provided between the first metallization layer 111 and the sidewalls 72. This gap may be filled by the casting compound 5 to provide electrical insulation between the sidewalls 72 and the first metallization layer 111.

As mentioned above, the semiconductor module 100 may further comprise one or more terminal elements 4, each terminal element 4 of the one or more terminal elements 4 comprising a first end 41 electrically connected to the first metallization layer 111, and a second end 42 protruding out of the casting compound 5 and out of the housing 7. As the terminal elements 4 generally also conduct currents, and as their second ends 42 protrude out of the casting compound 5, there may also be a risk of flashovers or short circuits occurring between one or more terminal elements 4 and the electrically conductive sidewalls 72 of the housing 7. This may depend, for example, on a distance between the respective terminal element 4 and the respective sidewall 72. For terminal elements 4 arranged centrally on the substrate 10, the risk of flashovers or short circuits may be low or even zero. If a terminal element 4 is arranged comparably close to one or more of the sidewalls 72 however, there may be an increased risk of flashovers or short circuits.

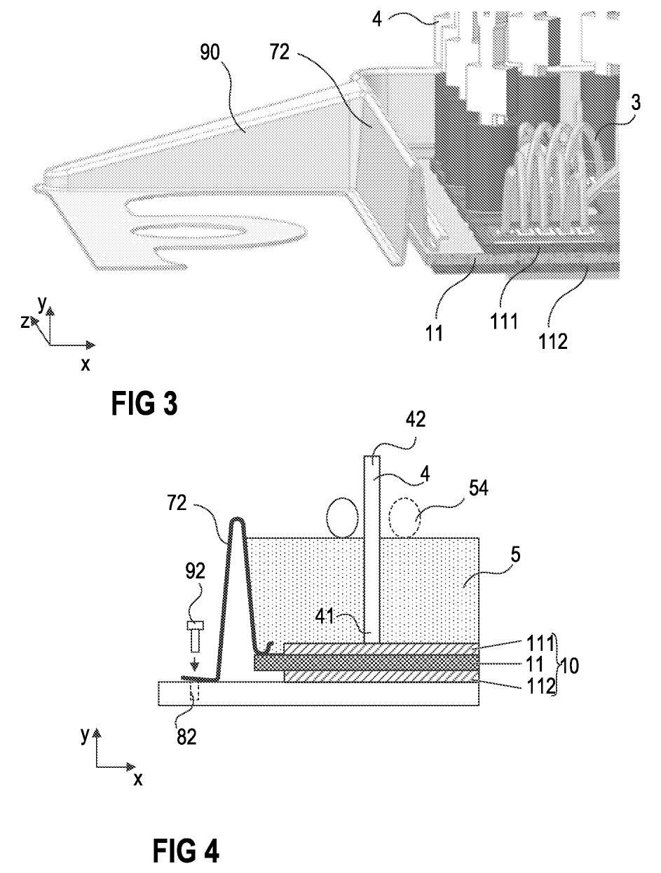

FIG. 3 schematically illustrates a three-dimensional cross-sectional view of an exemplary semiconductor module 100. In this example, some of a plurality of terminal elements 4 are arranged comparably close to one or more of the sidewalls 72 of the housing 7. This is also exemplarily illustrated in the cross-sectional view of FIG. 4, where one of the terminal elements 4 is arranged comparably close to one of the sidewalls 72. In order to electrically insulate terminal elements 4 from the sidewalls 72, the semiconductor module 100 may further comprise at least one first electrically insulating element 54 extending from a top surface of the casting compound 5 away from the substrate 10. The top surface of the casting compound 5 is a (usually essentially flat) surface facing away from the substrate 10. Each first electrically insulating element 54 of the at least one first electrically insulating element 54 may at least partly surround a different terminal element 4 of the one or more terminal elements 4. According to some examples, each first electrically insulating element 54 may completely surround one of the terminal elements 4. That is, a first electrically insulating element 54 may form a continuous loop around a terminal element 4 on top of the casting compound 5. It may, however, also be sufficient if a first electrically insulating element 54 is only arranged towards one side of the respective terminal element 4. In particular, it may be arranged between the terminal element 4 and at least one of the sidewalls 72, i.e., the sidewalls that are arranged closest to the respective terminal element 4 (see, e.g., solid left part of first electrically insulating element 54 of FIG. 4 – right section indicated in dashed lines may be omitted).

At least one first electrically insulating element 54 of the at least one first electrically insulating element 54 may consists of a material that is different from the material of the casting compound 5. That is, the one or more first electrically insulating elements 54 may be elements that are separate and distinct from the casting compound 5. The one or more first electrically insulating elements 54, however, may adhere to the casting compound 5 in order to remain in their desired positions on the casting compound 5. For example, one or more first electrically insulating elements 54 may be formed by means of suitable (2K) injection molding processes. That is, first electrically insulating elements 54 may be formed directly on a top surface of the casting compound 5. It is, however, also possible to form first electrically insulating elements 54 separately, and insert the finished first electrically insulating elements 54 into the semiconductor module 100 by placing them on the casting compound 5. First electrically insulating elements 54 may generally also be provided if two directly neighboring terminal elements 4 are arranged comparably close to each other. In this way, flashovers or short circuits between different neighboring terminal elements 4 may be prevented.

Some semiconductor modules 100 further comprise a printed circuit board 16 arranged distant from and in parallel to the substrate 10, wherein the printed circuit board 16 is mechanically and electrically coupled to the second ends 42 of one or more terminal elements 4. A printed circuit board 16 generally comprises conductor tracks which carry electrical currents. As is schematically illustrated in FIG. 5, each first electrically insulating element 54 of the at least one first electrically insulating element 54 may directly contact both the casting compound 5 and the printed circuit board 90. In this way, an electrical insulation may be provided between the terminal elements 4 and the printed circuit board 16 (i.e. the conductor tracks on a lower side of the printed circuit board 16).

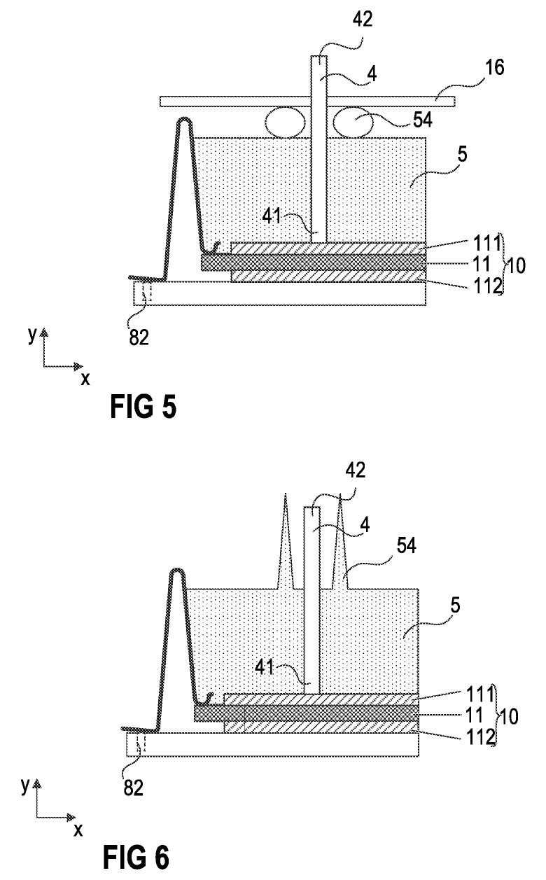

First electrically insulating elements 54 consisting of a different material than the casting compound 5, however, are only an example. As is schematically illustrated in FIG. 6, first electrically insulating elements 54 may also be integrally formed with the casting compound 5. That is, according to some embodiments, at least one first electrically insulating element 54 of the at least one first electrically insulating element 54 may consist of the same material as the casting compound 5. Such first electrically insulating elements 54 may be formed, e.g., by means of suitable injection molding processes. Another exemplary way of forming first electrically insulating elements 54 integrally with the casting compound 5 is by means of so-called liquid silicone rubber (LSR) processes. Materials that are typically used in LSR processes have similar electrical properties as standard potting materials used in semiconductor modules 100. However, materials used in LSR processes often cure (harden) significantly faster as compared to standard potting materials. In this way, it is possible to form an essentially homogenous potting body (casting compound 5) inside the housing with a 3D structured surface (one or more first electrically insulating elements 54 on a top surface of the potting body).

First electrically insulating elements 54 as illustrated in FIGS. 4 and 5 may generally also be combined with the integrally formed first electrically insulating elements 54 of FIG. 6. The specific shapes of the first electrically insulating elements 54 as illustrated in the figures are generally only examples. Any other shapes are generally possible.

When a printed circuit board 16 is attached to the semiconductor module 100, the one or more first electrically insulating elements 54 directly contact the casting compound 5 as well as the printed circuit board 16. In particular, the printed circuit board 16 may be pressed onto the one or more first electrically insulating elements 54 with a certain amount of force. In this way, each first electrically insulating element 54 of the one or more first electrically insulating elements 54 may be compressed to a certain degree. In this way, dielectric insulation between different terminal elements 4, between terminal elements 4 and the sidewalls 72 of the housing 7, as well as between terminal elements 4 and conductor tracks on a lower side of the printed circuit board 16 (lower side facing towards the substrate 10) may be provided. Further, possible creepage paths on a lower side of the printed circuit board 16 may be effectively interrupted.

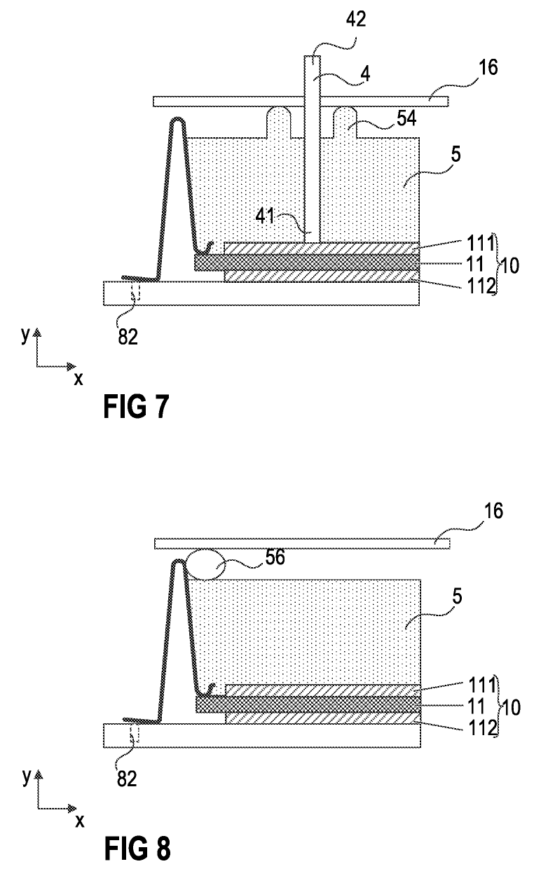

FIG. 6 schematically illustrates a first dielectrically insulating element 54 in an uncompressed state (no printed circuit board 16 mounted to the semiconductor module). FIG. 7 schematically illustrates a first dielectrically insulating element 54 in a compressed state (pressed between casting compound 5 and printed circuit board 16).

Instead of or in addition to the one or more first dielectrically insulating elements 54, a semiconductor module 100 according to embodiments of the disclosure may further comprise one or more second electrically insulating elements 56 extending from a top surface of the casting compound 5 away from the substrate 10. The top surface of the casting compound 5 is an essentially flat surface facing away from the substrate 10. A second electrically insulating element 56 may extend along the sidewalls 72 of the housing 7, for example. This is schematically illustrated in FIGS. 8, 9 and 10. In this way, dielectric insulation between conductor tracks on a printed circuit board 16 and the sidewalls 72 of the housing 7 may be provided.

As is schematically illustrated in FIG. 8, and similar to what has been described with respect to the first electrically insulating elements 54 above, a second electrically insulating element 56 may consist of a material that is different from the material of the casting compound 5. The second electrically insulating element 56 may directly contact the casting compound 5, the sidewalls 72, and the printed circuit board 16 (i.e. a lower side of the printed circuit board 16). In the example illustrated in FIG. 8, the second electrically insulating element 56 directly contacts the sidewalls 72 only in a horizontal direction x and only inside the internal volume defined by the sidewalls 72. This, however, is only an example.

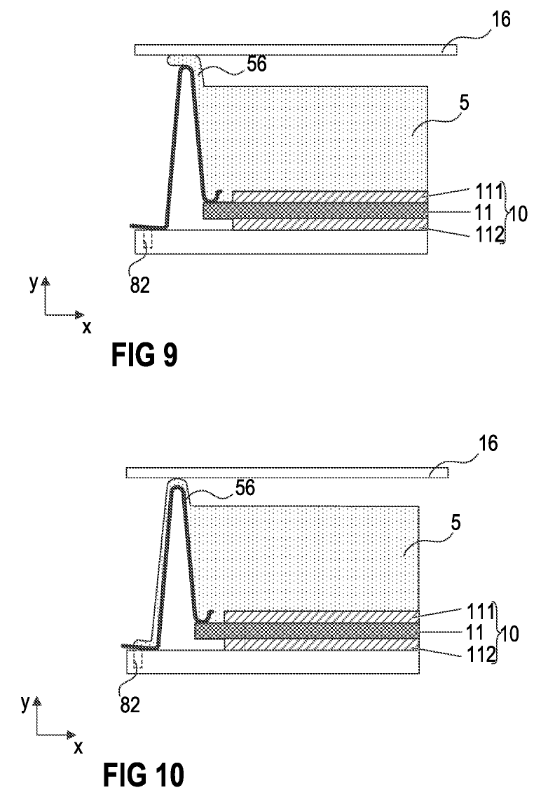

As is schematically illustrated in FIGS. 9 and 10, the second electrically insulating element 56 may also directly contact the sidewalls 72 in a vertical direction 72. In the example illustrated in FIG. 10, it also directly contacts the sidewalls 72 horizontally from outside of the housing 7.

In the examples illustrated in FIGS. 9 and 10, the second electrically insulating element 56 consists of the same material as the casting compound 5 and is integrally formed with the casting compound 5. A section of the second electrically insulating element 56 is (vertically) arranged between the sidewalls 72 and the printed circuit board 16. In these examples, the second electrically insulating element 56 at least partly coats the sidewalls 72, in order to dielectrically insulate them from the printed circuit board 16. A second electrically insulating element 56 may extend continuously along the entire circumference of the sidewalls 72. It is also contemplated that all or parts of the sidewalls 72, especially the upper portions of the sidewalls 72, could be coated with an insulating coating material prior to assembly and introduction of the casting material 5. In this embodiment, the coating material could be of a different material than that of the casting material 5.

In the examples illustrated in the figures, the housing 7 only comprises sidewalls 72, but no cover 74. It is, however, generally also possible that the housing 7 comprises a cover 74, similar to what is illustrated in FIG. 1. A cover 74 may be a separate component that is suitably attached to the sidewalls 72. It is, however, also possible that a cover 74 is integrally formed with the sidewalls 72. A cover 74 may either consist of an electrically insulating material, as in conventional semiconductor modules. It is, however, generally also possible that a cover 74, like the sidewalls 72, also consists of an electrically conducting material. In this case, additional measures may be taken in order to electrically insulate, e.g., the terminal elements 4 from the cover 74. Terminal elements 4 may protrude through respective openings formed in the cover 74. In order to dielectrically insulate the terminal elements 4 from an electrically conducting cover 74, respective first electrically insulating elements 54 may extend from a top surface of the casting compound 5 away from the substrate 10 and into the respective openings formed in the cover 74. That is, a section of a first electrically insulating element 54 may be arranged between the respective terminal element 4 and the cover 74 (i.e. horizontally surround the terminal element 4).

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A semiconductor module comprising:
a substrate comprising a dielectric insulation layer and at least a first metallization layer arranged on the dielectric insulation layer; and
a housing comprising sidewalls, the sidewalls defining an internal volume of the housing, wherein
the housing is arranged such that the substrate is arranged within the internal volume defined by the sidewalls, with the metallization layer facing the internal volume of the housing,
the housing comprises at least one mounting element for securely mounting the housing on a heat sink, and
the sidewalls of the housing consist of an electrically conducting material.

2. The semiconductor module of claim 1, wherein
each mounting element of the at least one mounting element comprises at least one first hole configured to receive a fastener for securely mounting the housing to a heat sink.

3. The semiconductor module of claim 1, wherein the electrically conducting material is a metal material.

4. The semiconductor module of claim 3, wherein the metal material comprises aluminum, copper, brass, tin, steel, or combinations thereof.

5. The semiconductor module of claim 1, further comprising a casting compound, the casting compound at least partly filling the internal volume defined by the sidewalls, covering the substrate, and at least partly covering components and electrical connections arranged on the substrate.

6. The semiconductor module of claim 5, wherein a portion of the casting compound is arranged between the sidewalls and the first metallization layer of the substrate, thereby electrically insulating the sidewalls from the first metallization layer.

7. The semiconductor module of claim 5, further comprising one or more terminal elements, each terminal element of the one or more terminal elements comprising a first end electrically connected to the first metallization layer, and a second end protruding out of the casting compound and out of the housing.

8. The semiconductor module of claim 7, wherein the second ends of the one or more terminal elements are configured to be mechanically and electrically coupled to a printed circuit board arranged distant from and in parallel to the substrate.

9. The semiconductor module of claim 7, further comprising at least one first electrically insulating element extending from a top surface of the casting compound away from the substrate, wherein the top surface of the casting compound is a surface facing away from the substrate, and wherein each first electrically insulating element of the at least one first electrically insulating element at least partly surrounds a different terminal element of the one or more terminal elements.

10. The semiconductor module of claim 9, wherein at least one first electrically insulating element of the at least one first electrically insulating element consists of a material that is different from the material of the casting compound.

11. The semiconductor module of claim 10, wherein the at least one first electrically insulating element directly contacts the casting compound and the printed circuit board.

12. The semiconductor module of claim 9, wherein at least one first electrically insulating element of the at least one first electrically insulating element consists of the same material as the casting compound and is integrally formed with the casting compound.

13. The semiconductor module of claim 8, further comprising a second electrically insulating element extending from a top surface of the casting compound away from the substrate, wherein the top surface of the casting compound is an essentially flat surface facing away from the substrate, and wherein the second electrically insulating element extends along the sidewalls of the housing.

14. The semiconductor module of claim 13, wherein the second electrically insulating element consists of a material that is different from the material of the casting compound, and wherein the second electrically insulating element directly contacts the casting compound, the sidewalls, and the printed circuit board.

15. The semiconductor module of claim 13, wherein the second electrically insulating element consists of the same material as the casting compound and is integrally formed with the casting compound, and wherein a section of the second electrically insulating element is arranged between the sidewalls and the printed circuit board.
